(19) United States
(12) Patent Application Publication
(10) Pub. No.: US 2012/0155024 A1
(43) Pub. Date: Jun. 21, 2012

(54) ELECTRONIC APPARATUS

(75) Inventor: Akifumi Yamaguchi, Kawasaki-shi (JP)

(73) Assignee: KABUSHIKI KAISHA TOSHIBA, Tokyo (JP)

(21) Appl. No.: 13/406,884

(22) Filed: Feb. 28, 2012

Related U.S. Application Data
(63) Continuation of application No. 12/943,593, filed on Nov. 10, 2010.

(30) Foreign Application Priority Data
Apr. 9, 2010 (JP) 2010-090890

(51) Int. Cl. H05K 7/20

(52) U.S. Cl. 361/692

(57) ABSTRACT

According to one embodiment, a television attachment device includes a case, a fan unit, a fin unit and a heat pipe. The fan unit includes a case, a fan main body rotatably provided inside the case, and a motor fixed to the inner surface of a second wall and rotating the fan main body. The fin unit is arranged adjacent to a first side portion of the case. The heat pipe includes a first end portion connected to a circuit component, and a second end portion opposed to the first end portion, close to the second wall and connected to the fin unit.

### CROSS-REFERENCE TO RELATED APPLICATIONS

This application is a continuation of Ser. No. 12/943,593 filed on Nov. 10, 2010, which is based upon and claims the benefit of priority from Japanese Patent Application No. 2010-090890, filed Apr. 9, 2010; the entire contents of both which are incorporated herein by reference.

### FIELD

Embodiments described herein relate generally to an electronic apparatus having a keyboard sub-assembly.

### BACKGROUND

Recent electronic apparatuses incorporate high-processing-power circuit components such as central processing units. Because such circuit components including the semiconductor elements are subject to an extremely high degree of integration and execute high-speed data processing, the circuit components produce a large amount of heat that requires effective heat management. This is generally achieved using a forced cooling subsystem in which a heat pipe conducts heat away from the circuit components being cooled to a heat-radiating fin located close to a fan which dissipates the heat by radiation assisted by the airflow produced by the fan.

As processors become faster and so produce more heat, an improved forced cooling subsystem that can cope with increased thermal throughput without increasing, or while even reducing, the noise produced by the subsystem becomes essential.

### BRIEF DESCRIPTION OF THE DRAWINGS

A general architecture that implements the various feature of the embodiments will now be described with reference to the drawings. The drawings and the associated descriptions are provided to illustrate the embodiments and not to limit the scope of the invention.

FIG. 1 is an exemplary perspective view of a television attachment device which is an example of the electronic apparatus according to the first embodiment.

FIG. 2 is an exemplary cross-sectional view of the television attachment device taken along the horizontal direction in FIG. 1.

FIG. 3 is an exemplary cross-sectional view of the cooling module of the television attachment device taken along the horizontal direction in FIG. 1.

FIG. 4 is an exemplary cross-sectional view of the cooling module shown in FIG. 3, taken along the line F4-F4.

FIG. 5 is an exemplary cross-sectional view of the cooling module shown in FIG. 3, taken along the line F5-F5.

FIG. 6 is an exemplary perspective view of a portable computer which is an example of an electronic apparatus according to the second embodiment.

FIG. 7 is an exemplary perspective view of the printed circuit board and the cooling module housed inside the portable computer shown in FIG. 6.

FIG. 8 is an exemplary cross-sectional view of the cooling module shown in FIG. 7, taken along the line F8-F8.

### DETAILED DESCRIPTION

Various embodiments will be described hereinafter with reference to the accompanying drawings.

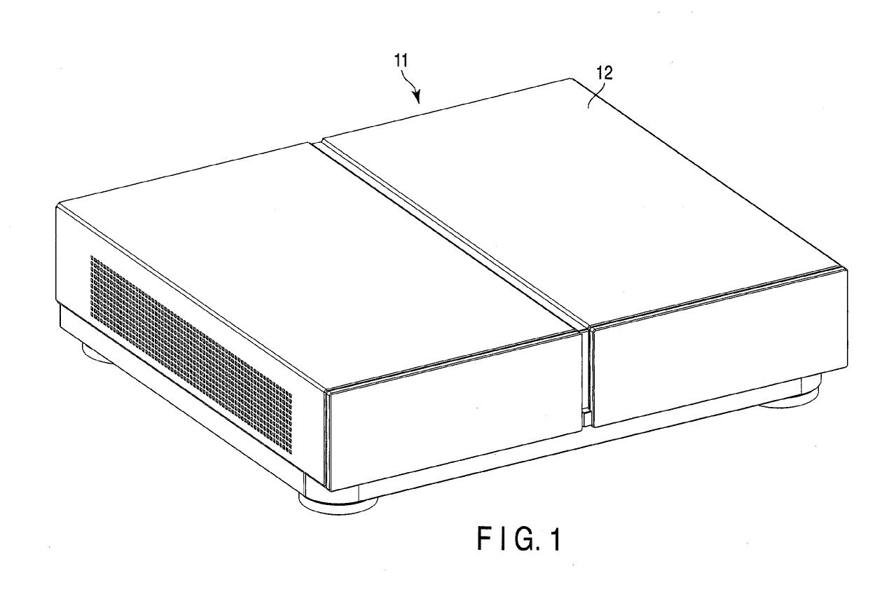

In general, according to one embodiment, a description will now be given of a first embodiment of a television attachment device which is an example of the electronic apparatus, with reference to FIGS. 1 to 5. The television attachment device is used to be connected to a flat television or the like, and the device has, for example, functions of receiving various types of TV programs, recording a plurality of TV programs at the same time, and recording a long-term program. With the television attachment device, digital terrestrial broadcasting, BS digital broadcasting and CS digital broadcasting can be received, and programs of these broadcasting systems can be recorded.

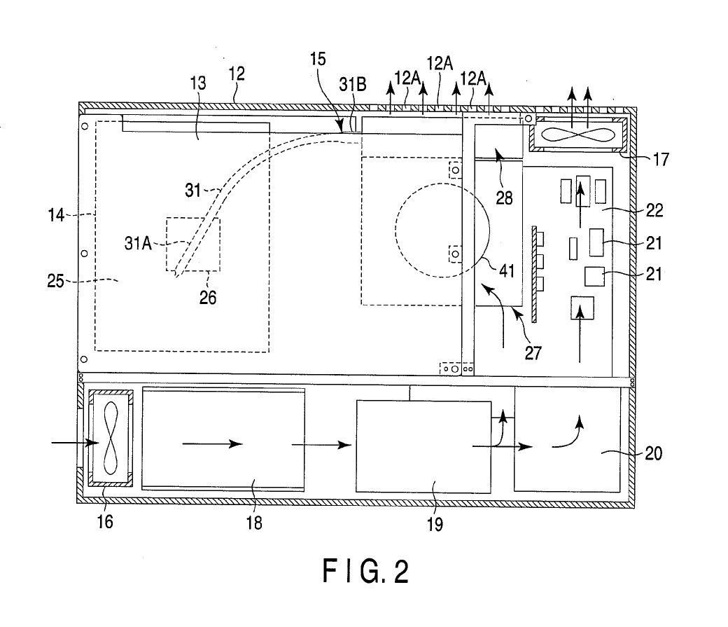

As shown in FIG. 1, a television attachment device 11 comprises a housing 12 which is a box-shaped enclosure of the device. As shown in FIG. 2, the television attachment device 11 comprises first and second printed circuit boards 13 and 14, and a cooling module 15 which cools a second circuit component 26 described below within the housing 12. In addition, the television attachment device 11 comprises first and second auxiliary fan units 16 and 17, first and second hard disk drive devices 18 and 19, which are memory devices for storing images, a card holder 20 to which an authentication card can be inserted and a power circuit board 22 on which a plurality of power circuit components 21 are mounted within the housing 12.

The first printed circuit board 13 is the so-called tuner substrate, and the first circuit component (heat-generating component), not shown in the figure, is secured on a surface of the first printed circuit board 13. In this embodiment, the first heat-generating component is a tuner, for example.

The second printed circuit board 14 is provided under the first printed circuit board 13. The second printed circuit board 14 is a main board (cell board) which performs centralized control of components of the television attachment device 11. The second printed circuit board 14 opposes the first printed circuit board 13 with a gap inbetween.

As shown in FIG. 2, the second printed circuit board 14 comprises the second printed wiring board 25, the second circuit component 26 (heat-generating component) secured on a surface (upper surface) of the second printed wiring board 25, and other heat-generating components not shown in the figure.

The second circuit component 26 comprises, for example, circuit components called cell processors. The other circuit components include a RAM.

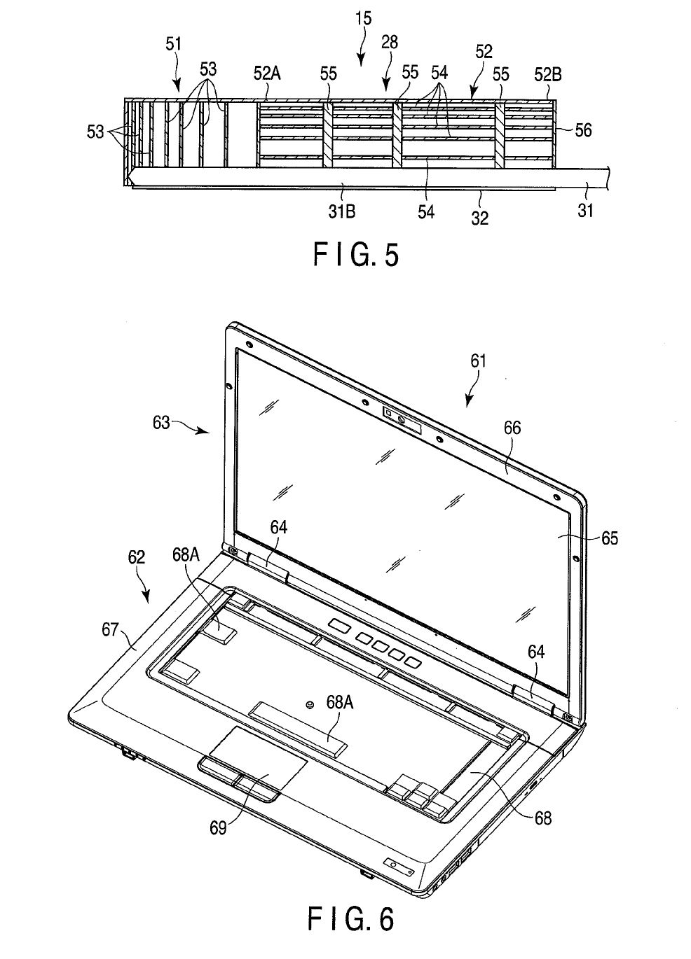

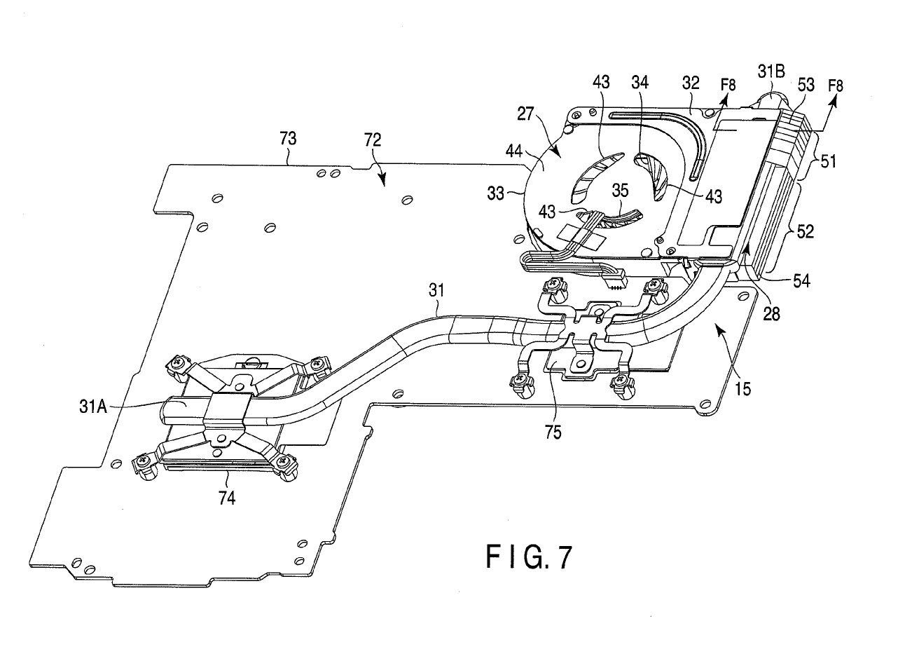

As shown in FIGS. 2 to 4, the cooling module 15 comprises a fan unit 27 which radiates heat generated by the second circuit component 26 through an opening 12A from the device, a fin unit 28 which is provided adjacent to the fan unit 27, a heat pipe 31 which is connected to the fin unit 28, a bracket 32 which fixes the heat pipe 31 to a case 33 of the fan unit 27. The bracket 32 has the same configuration as a bracket 32 shown in FIG. 7. The bracket 32 is formed, for example, of stainless steel and has an L shape. The bracket 32 is attached under both the fan unit 27 and the heat pipe 31. The bracket 32 is fixed to a second end portion 31B of the feat pipe 31 by brazing (soldering). As shown in FIG. 5, the second end portion 31B of the heat pipe 31 described below is placed between the fin unit 28 and the bracket 32.

The heat pipe 31 is formed by sealing a working fluid which is changeable between gas and liquid inside a tubular heat pipe main body formed, for example, of copper. The working fluid is water, for example, but not limited to water, but may be another medium such as alcohol. As shown in FIG. 2, the heat pipe 31 comprises a first end portion 31A thermally connected to the second circuit component 26 and a second end portion 31B provided on an opposite side of the first end portion 31A and thermally connected to the fin unit 28. As shown in FIG. 4, the second end portion 31B is located close to a second wall 44 of the case 33 of the fan unit 27 which is described below. The second end portion 31B is thermally connected to the fin unit 28 in this position. The second end portion 31B of the heat pipe 31 is fixed to the fin unit 28 by brazing (soldering).

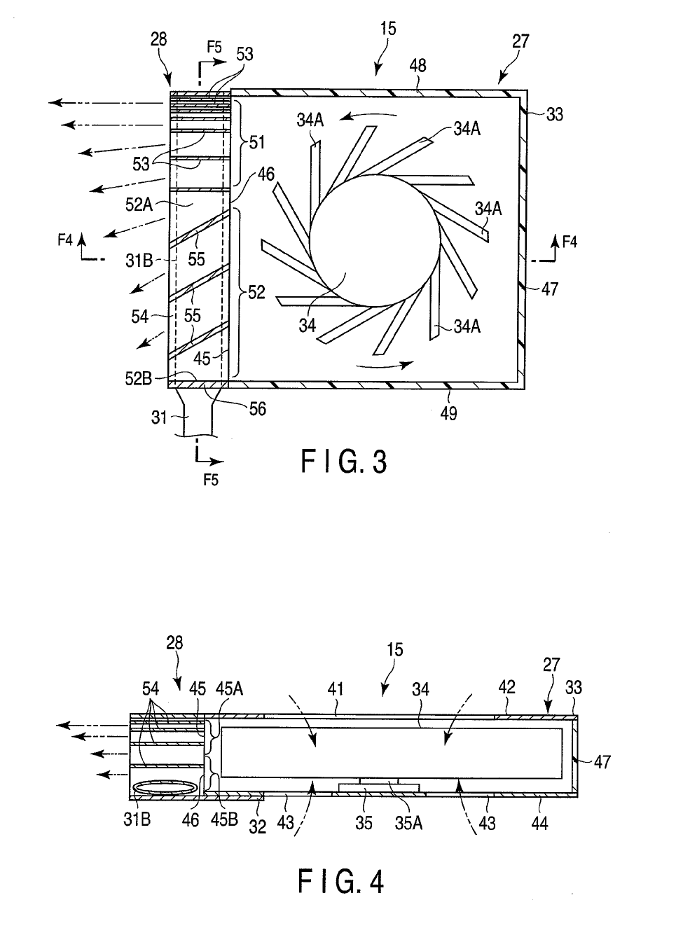

As shown in FIG. 4, the fan unit 27 comprises the case 33 which is a box-shaped enclosure of the unit, a fan main body 34 which is rotatable within the case 33, and a motor 35 which drives the rotation of the fan main body 34. The case 33 comprises a first wall 42 having a first suction opening 41, a second wall 44 opposed to the first wall 42 and having a second suction opening 43, and a first side portion 46 contiguous to the first wall 42 and the second wall 44 and having an exhaustion opening 45. As shown in FIG. 3, the case 33 further comprises a second side portion 47 opposed to the first side portion 46, a third side portion 48 contiguous to the first wall 42, the second wall 44, the first side portion 46 and the second side portion 47, and a fourth side portion 49 opposed to the third side portion 48.

As shown in FIGS. 3 and 4, the first wall 42 is a top plate and is formed, for example, of an aluminum plate material. The second wall 44 is a bottom plate and is formed, for example, of an aluminum plate material. The first to fourth side portions 46, 47, 48 and 49 are integrally formed as a frame by synthetic resin, for example. With the case 33 of this embodiment in which the first wall 42 and the second wall 44 are formed of the aluminum plate material, the thickness of the first wall 42 and the second wall 44 is decreased. This realizes a thinner fan unit 27 in comparison with the conventional fan unit.

The fan main body 34 comprises a plurality of fan blades 34A radially extending from the outer edge of the fan main body 34. The motor 35 is fixed on the inner surface (inside) of the second wall 44. The motor 35 comprises a rotation axis 35A, and the fan main body 34 is attached to the end of the rotation axis 35A. The motor 35 rotates the fan main body 34 in a counterclockwise direction in FIG. 3 so that the fan blades 34A close to the second side portion 47 move to the position close to the first side portion 46 through the position close to the third side portion 48.

As shown in FIGS. 3 to 5, the fin unit 28 is provided adjacent to the first side portion 46 of the case 33. The fin unit 28 comprises a first fin group 51 provided close to the third side portion 48 of the case 33, and a second fin group 52 provided far from the third side portion 48 of the case 33. That is, the first fin group 51 is provided closer to the third side portion 48 of the case 33 than the second fin group 52. The first fin group 51 and the second fin group 52 are integrally formed to form the fin unit 28.

The first fin group 51 includes a plurality of first fins 53 (vertical fins) which are arranged in parallel. Each of the first fins 53 is formed, for example, by a thin, square aluminum plate. The first fins 53 extend parallel to the third side portion 48 of the case 33, for example. The plurality of first fins 53 are arranged to be increasingly closer to one another toward the third side portion 48 of the case 33.

The second fin group 52 includes a plurality of second fins 54 (horizontal fins) which are arranged in parallel, a plurality of connection walls 55 which support the plurality of second fins 54 and thermally connect the second fins 54 to the heat pipe 31, and a support wall 56 provided at the ends of the second fins 54 of the second fin group 52.

The second fins 54 are inclined to, more specifically, perpendicular to, the first fins 53. Each second fin 54 extends parallel to the first wall 42 of the case 33, for example. Each second fins 54 is formed, for example, by a thin square aluminum plate. Each of the connection walls 55 is a plate formed, for example, by an aluminum material, and extends obliquely to the first fins 53. That is, the connection walls 55 extend in the direction of airflow from the fan main body 34 so as not to disturb the airflow from the fan main body 34. In addition, the support wall 56 is inclined (perpendicular) to the second fins 54. The support wall 56 is provided at an end portion 52B of the second fin group 52 opposed to an end portion 52A adjacent to the first fin group 51.

Before designing the cooling module 15 of this embodiment, the applicants researched the rate of exhaust air at each position of the exhaustion opening 45 of the fan unit 27. First, in the state where no operation is applied to the fan unit 27, and a voltage of 5V is applied to the fan unit 27, the rate of airflow is 150 L/min. In the case where the upper half of the exhaustion opening 45 in the vertical direction of the fan unit 27 is closed, the rate of airflow of the lower half of the exhaustion opening 45, i.e., a second half 45B close to the second wall 44, is 93 L/min. On the other hand, in the case where the lower half of the exhaustion opening 45 in the vertical direction of the fan unit 27 is closed, the rate of airflow of the upper half of the exhaustion opening 45, i.e., a first half 45A close to the first wall 42, is 102 L/min. Based on these results, it is confirmed that the rate of airflow exhausted from the exhaustion opening 45 varies, that is, the rate of airflow of the first half 45A close to the first wall 42 is greater than that of the second half 45B.

According to the first embodiment, the television attachment device 11 comprises: the case 33 which includes the first wall 42 having the first suction opening 41, the second wall 44 opposed to the first wall 42 and having the second suction opening 43, and the first side portion 46 contiguous to the first wall 42 and the second wall 44 and having the exhaustion opening 45; the fan unit 27 which includes the fan main body 34 rotatably provided within the case 33, and the motor 35 which is fixed to the inner surface of the second wall 44 and rotates the fan main body 34; the fin unit 28 which is provided adjacent to the first side portion 46 of the case 33 and includes the first fin group 51 having the first fins 53 arranged in parallel, and the second fin group 52 having the plurality of second fins 54 arranged in parallel and inclined to the first fins 53; and the heat pipe 31 which includes the first end portion 31A connected to the circuit components, and the second end portion 31B which is opposed to the first end portion 31A, provided close to the second wall 44 and connected to the fin unit 28.

With this structure, since the second end portion 31B of the heat pipe 31 is located in the position close to the second wall 44 of the case 33 in which the motor 35 is provided, the heat pipe 31 can be arranged in the position where the rate of airflow from the exhaustion opening 45 is low. In this structure, the airflow from the fan main body 34 is not disturbed by the heat pipe 31, and the noise generated from the fan unit 27 can be decreased.

In addition, the case 33 comprises the second side portion 47 opposed to the first side portion 46, the third side portion 48 contiguous to the first wall 42, the second wall 44, the first side portion 46 and the second side portion 47, and the fan main body 34 comprises the plurality of fan blades 34A and moves the fan blades 34A close to the second side portion 47 to the position close to the first side portion 46 through the position close to the third side portion 48, and the plurality of first fins 53 are arranged parallel to the third side portion 48 and arranged to be increasingly closer to one another toward the third side portion 48.

This structure realizes an increased density of the first fins 53 at the position close to the third side portion 48 at which the rate of airflow is high. In such a structure, the heat radiation of the first fin group 51 can be improved, and the heat radiation of the fin unit 28 can also be improved.

Further, the plurality of second fins 54 are arranged parallel to the first wall 42, and arranged to be increasingly closer to one another toward the first wall 42. This structure realizes an increased density of the second fins 54 at the position close to the first wall 42 at which the rate of airflow is high, and the heat radiation of the second fin group 52 can be improved. The heat radiation of the fin unit 28 can also be improved.

The television attachment device 11 further comprises the bracket 32 that fixes the heat pipe 31 to the case 33, the heat pipe 31 being placed between the fin unit 28 and the bracket 32. This structure prevents the heat pipe 31 from being misaligned relative to the case 33 of the fan unit 27. This further prevents noise generated from fan unit 27 due to misalignment of the heat pipe 31.

The second fin group 52 includes the support wall 56 which is inclined to the second fins 54, and the support wall 56 is provided at the end portion 52B opposed to the end portion 52A adjacent to the first fin group 51. This structure improves the mechanical strength of the second fin group 52.

Next, a second embodiment of the electronic apparatus will be explained with reference to FIGS. 6 to 8. In the second embodiment, a portable computer 61 is adopted as an example of the electronic apparatus. The appearance and the whole structure of the portable computer 61 are different from the first embodiment, but the basic structure of a cooling module 15 is the same as that of the first embodiment. The structural components or elements that are similar to those of the first embodiment will be denoted by the same reference symbols, and a repetitive description of such components or elements will be omitted.

The portable computer 61 comprises a main body unit 62, a display unit 63, and a hinge portion 64 provided between the main body unit 62 and the display unit 63. The hinge portion 64 rotatably supports the display unit 63.

The display unit 63 comprises a display 65 and a synthetic resin-made display case 66 which encloses the display 65.

The main body unit 62 comprises a synthetic resin-made housing 67 having a box-like shape, a keyboard unit 68 mounted on the housing 67, a touch pad 69 provided on the housing 67, and a printed circuit board 72 housed inside the housing 67. A part of keys 68A included in the keyboard unit 68 is shown in the figures.

The printed circuit board 72 comprises a printed wiring board 73, a first circuit component 74 (heat-generating component) and a second circuit component 75 (heat-generating component) mounted on the printed wiring board 73. The first circuit component 74 is a CPU, for example. The second circuit component 75 is a graphics chip, for example.

The cooling module 15 according to the second embodiment has similar configurations to those shown in FIGS. 3 to 5. The cooling module 15 comprises a fan unit 27 which radiates heat generated from the first circuit component 74 and the second circuit component 75, a fin unit 28 provided adjacent to the fan unit 27, a heat pipe 31 connected to the fin unit 28, and a bracket 32 which fixes the heat pipe 31 to the fan unit 27. The bracket 32 is formed, for example, of stainless steel and has an L shape. The bracket 32 is attached under both the fan unit 27 and the heat pipe 31. A second end portion 31B of the heat pipe 31 described below is provided between the fin unit 28 and the bracket 32.

The heat pipe 31 comprises a first end portion 31A thermally connected to the first circuit component 74 and the second end portion 31B provided on an opposite side of the first end portion 31A and thermally connected to the fin unit 28. The heat pipe 31 is thermally connected to the second circuit component 75 between the first and second end portions 31A and 31B. The second end portion 31B is located close to a second wall 44 of the case 33 of the fan unit 27 described below. The second end portion 31B is thermally connected to the fin unit 28 in this position.

The fin unit 28 comprises a first fin group 51 provided close to a third side portion 48 of the case 33, and a second fin group 52 provided far from the third side portion 48 of the case 33. That is, the first fin group 51 is provided closer to the third side portion 48 of the case 33 than the second fin group 52. The first fin group 51 and the second fin group 52 are integrally formed to form the fin unit 28.

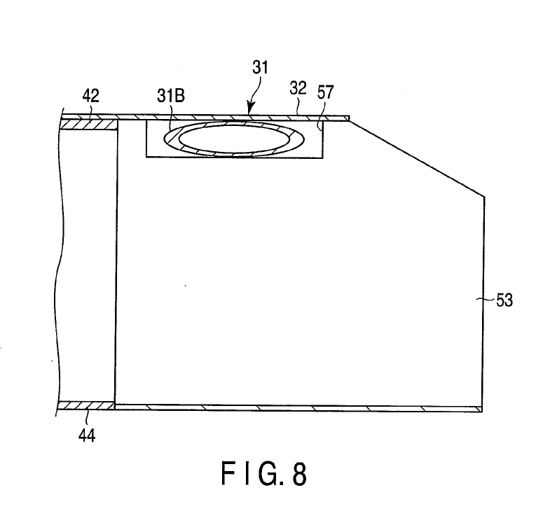

The first fin group 51 includes a plurality of first fins 53 (vertical fins) which are arranged in parallel. Each of the first fins 53 is arranged parallel to the third side portion 48 of the case 33, for example (see FIG. 3). The plurality of first fins 53 are arranged to be increasingly closer to one another toward the third side portion 48 of the case 33. As shown in FIG. 8, each first fin 53 has a notch 57 in which the second end portion 31B of the heat pipe 31 is housed. The first fins 53 are thermally connected to the second end portion 31B in the position closer to the end than the second fins 54. The notch 57 of each of the first fins 53 and the bracket 32 enclose and support the second end portion 31B of the heat pipe 31.

The second fin group 52 includes a plurality of second fins 54 (horizontal fins) which are arranged in parallel. The second fins 54 are inclined to, more specifically, perpendicular to, the first fins 53. The plurality of second fins 54 are provided parallel to a first wall 42 of the case 33, for example (see FIG. 4).

According to the second embodiment, noise is prevented from being generated from the fin unit 28. The density of the first fins 53 is increased at the position close to the third side portion 48 at which the rate of airflow is high, and the density of the second fins 54 is increased at the position close to the first wall 42 at which the rate of airflow is high. This structure improves the heat radiation of the fin unit 28.

The electronic apparatus is not limited to the television attachment device 11 or the portable computer 61 described in the embodiments, but may be applicable to other electronic apparatuses, such as a cellular phone.

Furthermore, it is only natural that the electronic device of the present invention can be remodeled into various different versions as long as the essence of the invention does not fall outside the scope thereof.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic apparatus comprising:
a fan unit comprising a case which comprises a first wall including a first suction opening, a second wall opposed to the first wall and including a second suction opening, and a first side portion extending between the first wall and the second wall and including an exhaust opening, a fan which is rotatably provided at a place close to the first wall and inside the case, and a motor which is fixed to an inner surface of the second wall and configured to rotate the fan;
a fin unit provided near the first side portion of the case and comprising a first fin group including a plurality of first fins arranged parallel to one another and orthogonal to the heat pipe, and a second fin group including a plurality of second fins arranged parallel to one another and to the heat pipe; and
the heat pipe comprising a first end portion connected to a circuit component, and a second end portion, wherein the second end portion is opposed to the first end portion, is near the second wall, and is connected to the fin unit.

2. The electronic apparatus of claim 1, wherein the plurality of first fins extend in a direction orthogonal to the first wall, and the plurality of second fins extend in a direction parallel to the first wall.

3. The electronic apparatus of claim 1, wherein the plurality of first fins are vertically arranged, and the plurality of second fins are horizontally arranged.

4. The electronic apparatus of claim 1, wherein:
the case comprises a second side portion opposed to the first side portion, and a third side portion contiguous with the first wall, the second wall, the first side portion, and the second side portion,
the fan comprises a plurality of fan blades and is configured to rotate the fan blades such that the fan blades near the second side portion are moved to a position near the first side portion through a position near the third side portion, and
the plurality of first fins are arranged parallel to the third side portion and arranged to be increasingly closer to one another toward the third side portion.

5. The electronic apparatus of claim 1, wherein the plurality of second fins are arranged parallel to the first wall and arranged to be increasingly closer to one another toward the first wall.

6. The electronic apparatus of claim 1, wherein
the second fin is connected to a support wall inclined to the second fins.

7. The electronic apparatus of claim 1, further comprising a bracket configured to fix the case to the heat pipe,
wherein the heat pipe is provided between the fin unit and the bracket.

8. The electronic apparatus of claim 7, wherein the heat pipe is provided between the bracket and the second fins.

9. The electronic apparatus of claim 1, wherein the second fins is connected to a connection wall inclined to the second fins.

10. The electronic apparatus of claim 9, wherein the connection wall extends obliquely to the first fins.

11. An electronic apparatus comprising:
a housing including an upper surface, a bottom surface and a side surface including an opening;
a fan unit housed in the housing;
a fin unit housed in the housing; and
a heat generator housed in the housing and thermally connected to the fin unit,
wherein the fan unit comprises a case comprising a first wall facing the upper surface and including a first suction opening, a second wall facing the bottom surface and including a second suction opening, and a first side portion extending between the first wall and the second wall and including an exhaust opening through which air from a fan blows toward the opening, the fan being rotatably provided at a place near the first wall and inside the case; and a motor fixed to the second wall and configured to rotate the fan, and
wherein the fin unit is configured to receive exhaust from the exhaust opening in proximity to the first side portion of the case and comprises a plurality of first fins facing one of the upper surface and the bottom surface and extending in a thickness direction of the case and arranged in parallel, and a plurality of second fins arranged parallel to one another and orthogonal to the upper surface and the bottom surface.

12. The electronic apparatus of claim 11, wherein the plurality of first fins extend along the first side portion, and the plurality of second fins extend along the first wall.

13. The electronic apparatus of claim 12, wherein the plurality of second fins face the housing.

14. The electronic apparatus of claim 11, further comprising a heat pipe comprising a first end portion thermally connected to the heat generator, and a second end portion, wherein the second end portion is opposed to the first end portion, is near the second wall, and is thermally connected to the fin unit.

15. A cooling module comprising:
a fan unit comprising a case which comprises a first wall including a first suction opening, a second wall opposed to the first wall and including a second suction opening, and a first side portion contiguous with the first wall and the second wall and including an exhaust opening, a fan main body which is rotatably provided close to the first wall and inside the case, and a motor which is fixed to an inner surface of the second wall and configured to rotate the fan main body;
a fin unit adjacent to the first side portion of the case and comprising a first fin group including a plurality of first fins arranged parallel to one another and orthogonal to a heat pipe, and a second fin group including a plurality of second fins and arranged parallel to one another and to the heat pipe; and
the heat pipe comprising a first end portion connected to a circuit component, and a second end portion opposed to the first end portion, near the second wall, and connected to the fin unit.
